(19) United States
(12) Patent Application Publication
(10) Pub. No.: US 2010/0006815 A1
(43) Pub. Date: Jan. 14, 2010

(54) PHASE CHANGE MEMORY AND RECORDING MATERIAL FOR PHASE CHANGE MEMORY

(75) Inventors: Jyunji TOMINAGA, Tsukuba-shi (JP); Paul FONS, Tsukuba-shi (JP); Alexander V. KOLOBOV, Tsukuba-shi (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory, Inc., Tokyo (JP)

(21) Appl. No.: 12/498,926

(22) Filed: Jul. 7, 2009

(30) Foreign Application Priority Data
Jul. 9, 2008 (JP) 2008-179341

(51) Int. Cl. H01L 45/00; H01B 1/06

(52) U.S. Cl. 257/4; 252/519.4; 257/E45.002

(57) ABSTRACT

A recording material for a phase change solid memory may include a uniform-mixed phase that includes: at least one of a Te-containing alkali metal iodide phase and a Te-containing silver iodide phase, and an Sb—Te alloy phase. The recording material shows at least one of a phase change and a phase separation which changes at least one of optical property and electrical property of the recording material.

### BACKGROUND OF THE INVENTION

1. Field of the Invention

The present invention generally relates to a recording material for a phase change memory and a phase change memory.

Priority is claimed on Japanese Patent Application No. 2008-179341, filed Jul. 9, 2008, the content of which is incorporated herein by reference.

2. Description of Related Art

A phase change memory performs recording and erasing of data by change in physical property of a recording material. The change is caused by a primary phase transformation of the recording material. The primary phase transformation is made between crystal state and amorphous state of the recording material. Typically, the recording material may be a Te-containing chalcogen compound. The phase change memory has been designed based on those fundamental principles. In some cases, the phase change memory may be a phase change random access memory, hereinafter referred to as a phase change RAM, which is disposed in Japanese Unexamined Patent Application, First Publication, No. 2002-203392.

The recording material that is used for the phase change RAM in recording and erasing of data can generally be formed by utilizing a vacuum film formation method such as a sputtering method between electrodes. In general, the recording material can be realized by a single layered structure of an alloy thin film which is formed by using a compound target.

For example, when the Te-containing chalcogen compound is used as the recording material of a solid memory, the Te-containing chalcogen compound has a difference in resistance between the crystal state and the amorphous state. The resistance difference can be utilized in recording and erasing of data. When a ternary alloy, for example, a Ge—Sb—Te alloy, is used as the recording material of a solid memory, the resistance difference will be approximately two digits at the average.

Meanwhile, the resistance difference between the crystal state and the amorphous state will gradually decrease by repeating recording and erasing of data. The largest possible resistance difference of the recording material would be preferable, if the recording material is used for a memory. Those are disclosed in p. 114 of “Technology and Materials for Future Optical Memories,” by Masahiro Okuda, CMC Publishing Co., Ltd., Jan. 31, 2004.

An alloy composition for increasing the speeds of rewriting of data, for example, recording and erasing of data in the solid memory, has been developed based on the experimental results. At the present, a Ge—Sb—Te alloy which atomic ratio is 2:2:5 is generally used. There is no theoretical underpinning that this ternary compound material is best for the recording material of the phase change solid memory. Those are disclosed in p. 209 of “Basics and Applications of Optical Disk Storage,” by Yoshito Tsunoda et al., The Institute of Electronics, Information and Communication Engineers, Oct. 15, 1995.

The chalcogen compound including Ge, Sb and Te has been realized be used as the recording material which, for example, can be used as optical recording mediums. As described above, the resistance difference between the crystal state and the amorphous state is approximately two digits at the average when the recording material is used for an electric memory utilizing the resistance difference between the crystal state and the amorphous state. When the number of repeating times of recording and erasing of data exceeds 10¹⁰, the resistance difference between the crystal state and the amorphous state is gradually starting to decrease, thereby causing error in recording and erasing of data. As the number of repeating times of recording and erasing of data further increases, the resistance difference between the crystal state and the amorphous state will further decrease. The decrease of the resistance difference will cause increasing the time of error in recording and erasing of data. When the memory is used as a DRAM that utilizes the resistance difference and that needs a large number of the repeating times of the recording and erasing of data, there is a problem with the limited number of the repeating times.

The solid memory that needs to perform high speed operation for DRAMs is largely different from optical memory in the required time for rewriting of data. Thus, there is the issue to realize high speed switching operation. However, there is no theoretical underpinning that the Ge—Sb—Te alloy which atomic ratio is 2:2:5 is best for the recording material of the electrical memory. And a working of the phase change between the crystal state and the amorphous state has not been resolved. In recent years, there was studied the mechanism of the switching operation between the crystallized structure and the amorphous structure that shows the above property. Those are disposed in pp. 7020-7028 of “Structure of Laser-Crystallized Ge₂Sb₂₊ₓTe₅ Sputtered Thin Films for Use in Optical Memory,” by Yamada, T. Matsunaga, Journal of Applied Physics, Vol. 88, 2000, for example.

### SUMMARY

A recording material for a phase change solid memory may include a uniform-mixed phase that includes: at least one of a Te-containing alkali metal iodide phase and a Te-containing silver iodide phase, and an Sb—Te alloy phase. The recording material shows at least one of a phase change and a phase separation which changes at least one of optical property and electrical property of the recording material.

A recording material for a phase change solid memory may include a uniform-mixed phase that includes at least one of a Te-containing alkali metal iodide phase and a Te-containing silver iodide phase, and an Sb—Te alloy phase. The recording material has a crystal structure that includes a first pair of a tellurium atom and either an alkali metal atom or a silver atom, and a second pair of other tellurium atom and an iodide atom. The recording material shows a transition between first and second states. The transition between the first and second states is made by at least one of first and second displacement set. The first displacement set includes a first displacement of the tellurium atom belonging to the first pair and a second displacement of either the alkali metal atom or the silver atom belonging to the first pair. The directions of the first and second displacements are generally anti-parallel to each other.

The second displacement set includes a third displacement of the other tellurium atom belonging to the second pair and a fourth displacement of the iodide atom belonging to the second pair, the directions of the third and fourth displacements are generally anti-parallel to each other.

A phase change solid memory may include a recording material. The recording material may include a uniform-mixed phase that includes at least one of a Te-containing alkali metal iodide phase and a Te-containing silver iodide phase; and an Sb—Te alloy phase. The recording material shows at least one of a phase change and a phase separation which changes at least one of optical property and electrical property of the recording material.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a view of the crystal state of the Ge—Sb—Te compound;

FIG. 2 is a view of the amorphous state of the Ge—Sb—Te compound;

FIG. 3 is a view of a crystal structure of an Sb—Te compound containing alkali metal iodide or silver iodide, which is used as a recording material of a phase change RAM in a first state of the recording and erasing in accordance with an embodiment of the present invention; and

FIG. 4 is a view of a crystal structure of the Sb—Te compound containing alkali metal iodide or silver iodide, which is used as a recording material of a phase change RAM in a second state of the recording and erasing in accordance with the embodiment of the present invention.

### DETAILED DESCRIPTION OF THE PREFERRED EMBODIMENTS

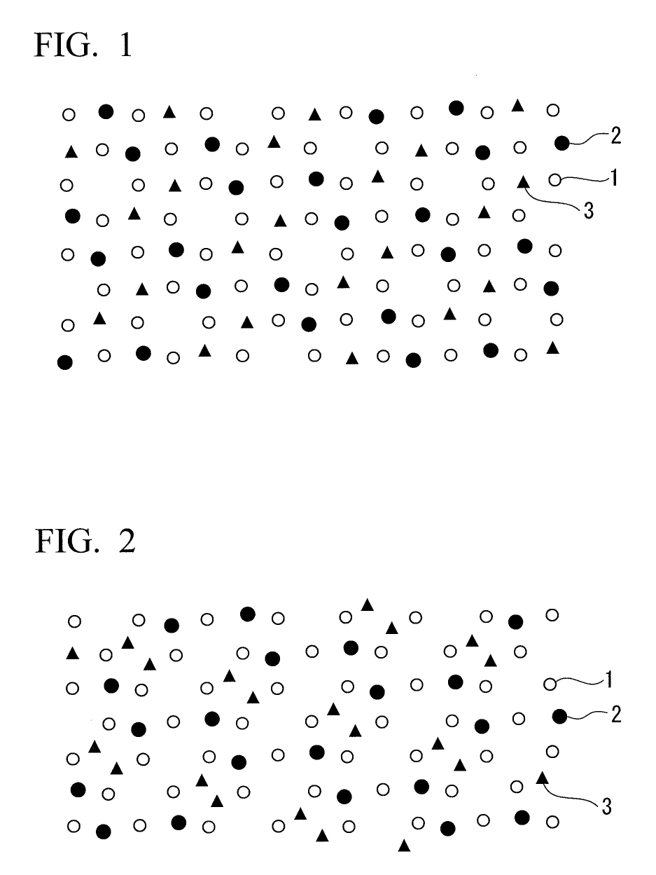

Before describing the present invention, the related art will be explained in detail with reference to FIGS. 1 and 2, in order to facilitate the understanding of the present invention.

There has been performed analyze of the crystal structure of the Ge—Sb—Te compound by using an orbit radiation device. The analyze is described in “Understanding the phase-change mechanism of rewritable optical media” by A. V. Kolobov et al., Nature Materials 3, 703, 2004.

Typical result of the above analyzes will be described. FIG. 1 is a view of the crystal state of the Ge—Sb—Te compound. The crystal of the Ge—Sb—Te compounds are constituted by Te atoms 1, Sb atoms 2 and Ge atoms 3. Sb atoms 2 and Ge atoms 3 are displaced from the site of Cl in the crystal structure of NaCl. The crystal structure of the Ge—Sb—Te compound is similar to simple cubic lattice of NaCl. The crystal structure of the Ge—Sb—Te compound is distorted. Te atom 1 is at a site corresponding to Na of the NaCl structure, and Sb atom 2 or Ge atom 3 is at the site corresponding to Cl of the NaCl structure.

FIG. 2 is a view of the amorphous state of the Ge—Sb—Te compound. The atomic arrangement in the amorphous state of the Ge—Sb—Te compounds is not random. The configuration of the amorphous state of the Ge—Sb—Te compounds is similar to a NaCl structure that is distorted a little maintaining the configuration. In the crystal structure, the Ge atoms 3 shifted 2 angstrom toward the Te atoms 1. But the crystal structure is slightly shifted, while maintaining the unit of the crystal structure. The displacement of the Ge atoms 3 causes that the Ge—Sb—Te compound slightly comes toward ferroelectric states.

It was discovered that the above described two phenomena will appear not in the ternary alloy of Ge—Sb—Te but in the other ternary alloy. A new material that shows a larger difference of electric resistance between in its crystal state and in its amorphous state has been discovered by experiments and simulations. The new material will permit the phase change RAM to perform high speed switching operation.

It was discovered that in some cases, a new alloy may be superior in memory characteristics to the Ge—Sb—Te alloy. The new alloy has a binary alloy phase which is constituted by two difference phases. The first phase is Te-containing alkali metal iodide phase or the Te-containing silver iodide phase. The second phase is the Sb—Te alloy phase.

There is provided a new recording material for the phase change solid memory such as the phase change RAM utilizing the phenomenon that the phase change of the new recording material or a phase separation of the new recording material will provide optical or electrical properties of the new recording material. The new recording material has a uniformly mixed phase. This phase includes two different phases. The first phase is a Te-containing alkali metal iodide phase or a Te-containing silver iodide phase. The second phase is an Sb—Te alloy phase. The dimension of each of the phases in a uniaxial direction is equal to or less than 5 nm. The recording material has a micro structure of two mixed phases which may be regarded as the uniformly mixed phase in a long scale.

The invention will be now described herein with reference to illustrative embodiments. Those skilled in the art will recognize that many alternative embodiments can be accomplished using the teachings of the present invention and that the invention is not limited to the embodiments illustrated for explanatory purposes.

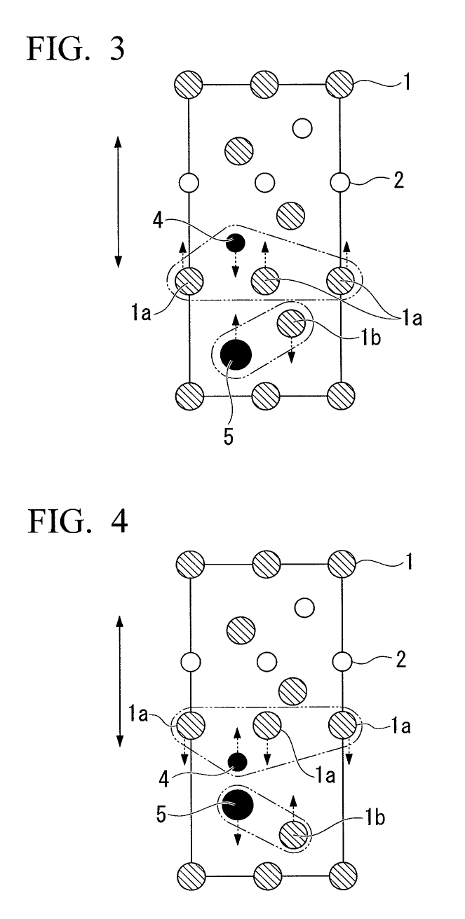

FIG. 3 is a view of a crystal structure of the Sb—Te compound containing alkali metal iodide or silver iodide, which is used as the recording material of the solid memory such as the phase change RAM in a first state of the recording and erasing in accordance with an embodiment of the present invention. FIG. 4 is a view of a crystal structure of the Sb—Te compound containing alkali metal iodide or silver iodide, which is used as the recording material of the solid memory such as the phase change RAM in a second state of the recording and erasing in accordance with the embodiment of the present invention.

A recording material for a phase change solid memory may include a uniform-mixed phase that includes at least one of a Te-containing alkali metal iodide phase and a Te-containing silver iodide phase, and an Sb—Te alloy phase. The recording material shows at least one of a phase change and a phase separation which changes at least one of optical property and electrical property of the recording material. The uniform-mixed phase is that each of the Sb—Te alloy phase and the at least one of the Te-containing alkali metal iodide phase and the Te-containing silver iodide phase has a dimension of not more than 5 nm in an uniaxial direction. The uniaxial direction is represented by an arrow mark in FIGS. 3 and 4.

The recording material has a crystal structure shown in FIGS. 3 and 4. The crystal structure includes a first pair of a tellurium atom 1a and either an alkali metal atom 4 or a silver atom 4, and a second pair of other tellurium atom 1b and an iodide atom 5. The first pair is encompassed by a closed broken line. The second pair is encompassed by another closed broken line. The recording material shows a transition between first and second states. The first state is shown in FIG. 3. The second state is shown in FIG. 4. One of the first and second states is a state where the phase change solid memory is placed in the writing. The other of the first and second states is a state where the phase change solid memory is placed in the erasing.

The recording material shows the transition between the first and second states which can be made by at least one of first and second site exchanges. The first site exchange is made between the position in the uniaxial direction of the site of the tellurium atom 1a belonging to the first pair and the position in the uniaxial direction of the site of either the alkali metal atom 4 or the silver atom 4 belonging to the first pair.

The first site exchange is involved in the transition from the first state of FIG. 3 to the second state of FIG. 4. The first site exchange is made by the displacements of the tellurium atom I a, either the alkali metal atom 4 or the silver atom 4, the tellurium atom 1b and the iodide atom 5. The directions of the displacements for the first site exchange are shown by the arrow marks of FIG. 3.

The second site exchange is made between the position in the uniaxial direction of the site of the other tellurium atom 1b belonging to the second pair and the position in the uniaxial direction of the side of the iodide atom 5 belonging to the second pair. The second site exchange is involved in the other transition from the second state of FIG. 4 to the first state of FIG. 3. The second site exchange is made by the other displacements of the tellurium atom 1a, either the alkali metal atom 4 or the silver atom 4, the tellurium atom 1b and the iodide atom 5. The directions of the other displacements for the second site exchange are shown by the arrow marks of FIG. 4.

In the first state, as shown in FIG. 3, a first distance in an uniaxial direction between the tellurium atom 1a belonging to the first pair and the other tellurium atom 1b belonging to the second pair is smaller than a second distance in the uniaxial direction between either the alkali metal atom 4 or the silver atom 4 belonging to the first pair and the iodide atom 5 belonging to the second pair. In the second state, as shown in FIG. 4, the first distance is greater than the second distance.

In the first state, as shown in FIG. 3, the sites of the tellurium atom 1a belonging to the first pair and the other tellurium atom 1b belonging to the second pair are positioned in the uniaxial direction inside between the sites of either the alkali metal atom 4 or the silver atom 4 belonging to the first pair and the iodide atom 5 belonging to the second pair. In the second state, as shown in FIG. 4, the sites of either the alkali metal atom 4 or the silver atom 4 belonging to the first pair and the iodide atom 5 belonging to the second pair are positioned in the uniaxial direction inside between the sites of the tellurium atom 1a belonging to the first pair and the other tellurium atom 1b belonging to the second pair.

The direction of the displacements of the tellurium atom 1a and the iodide atom 5 is generally anti-parallel to the direction of the displacements of the tellurium atom 1b and either the alkali metal atom 4 or the silver atom 4 as shown in FIGS. 3 and 4.

The above described uniaxial direction is a direction that is parallel to an axis of the crystal structure of the recording material. In some cases, the crystal structure may be a hexagonal crystal, where c-axis is the axis parallel to the uniaxial direction shown by the arrow marks of FIGS. 3 and 4.

The recording material in the first state of FIG. 3 is significantly different in electrical resistance from that in the second state of FIG. 4. The above-described displacements of the tellurium atoms 1a and 1b, either the alkali metal atom 4 or the silver atom 4 and the iodide atom 5 permit stable switching between the first and second states. The stable switching permits increasing the repeating number of recording and erasing of data. The stable switching permits increasing the speeds of the switching.

Next, method of forming alloy phases will be described. To form the alloy phases using the sputtering method, glass target of AgI corresponding to the silver iodide or target of alkali tellurium compound corresponding to the alkali metal iodide and iodide gas are used. And compound target of Sb₂Te₃ or target of Sb or Te is used. By measuring in advance the speeds of forming a film by the electric power for the sputtering, the alloy phases can be easily formed only by controlling thickness of the film by the film-forming time.

### EXAMPLE 1

A first phase change RAM had a basic configuration of normal self-resistance-heated type. Electrodes of the first phase change RAM were made of TiN. A recording film of the first phase change RAM was made of LiISb₂Te₅. The recording film has a thickness of 20 nm. The size of cell of the first phase change RAM was 100 nm×100 nm. Current values of the first phase change RAM were measured by applying voltage to the first phase change RAM. The application of the voltage was made based on a program. When the second phase change RAM performed recording of data, the pulse current was 0.2 mA with 5 ns of pulse time. When the first phase change RAM performed erasing of data, the pulse current was 0.05 mA with 60 ns of pulse time. A large resistance difference such as approximately 4-digits number was obtained between the recording state and the erasing state. The limit of the number of the repeating times of recording and erasing of data was 10¹⁴. The switching speed, for example, the speed of recording and erasing of data was 0.8 ns.

### EXAMPLE 2

A second phase change RAM had a basic configuration of the normal self-resistance-heated type like the first phase change RAM. A recording film of the second phase change RAM was made of AgISb₂Te₅. The recording film has a thickness of 20 nm. The size of cell of the second phase change RAM was 100 nm×100 nm. Current values of the second phase change RAM were measured by applying voltage to the second phase change RAM. The application of the voltage was made based on a program. When the second phase change RAM performed recording of data, the pulse current was 0.3 mA with 5 ns of pulse time. When the second phase change RAM performed erasing of data, the pulse current was 0.07 mA with 60 ns of pulse time. A large resistance difference such as approximately 4-digits number was obtained between the recording state and the erasing state. The limit of the number of the repeating times of recording and erasing of data was 10¹⁵. The switching speed, for example, the speed of recording and erasing of data was 1.0 ns.

### COMPARATIVE EXAMPLE

A third phase change RAM was prepared for a comparison, having a basic configuration of the normal self-resistance-heated type like the first phase change RAM. A recording film of the third phase change RAM was made of Ge₂Sb₂Te₅. The recording film has a thickness of 20 nm. The size of cell of the third phase change RAM was 100 nm×100 nm. Current values of the third phase change RAM were measured by applying voltage to the third phase change RAM. The application of the voltage is made based on a program. When the third phase change RAM performed recording of data, the pulse current was 1.0 mA with 5 ns of pulse time. When the first phase change RAM performed erasing of data, the pulse current was 0.4 mA with 60 ns of pulse time. The limit of the number of the repeating times of recording and erasing of data was 10¹². The switching speed, for example, the speed of recording and erasing of data was 20 ns.

As described above, it was confirmed that the phase change RAMs of the first and second examples using the Sb—Te alloy containing the alkali metal iodide or the silver iodide had more resistance difference between states of recording and erasing of data and achieved more number of repeating times of recording and erasing of data than the phase change RAM using the Ge—Sb—Te compounds.

The recording material is typically used as a channel of the solid memory such as the phase change RAM. The description of the above is applied to the recording material for the solid memory such as the phase change RAM. The invention is not limited to the recording material for the solid memory such as the phase change RAM, but applied to every solid memories and other related devices.

It is apparent that the present invention is not limited to the above embodiments, but may be modified and changed without departing from the scope and spirit of the invention.

What is claimed is:

1. A recording material for a phase change solid memory, the recording material comprising: a uniform-mixed phase that includes:
at least one of a Te-containing alkali metal iodide phase and a Te-containing silver iodide phase; and
an Sb—Te alloy phase,
wherein the recording material shows at least one of a phase change and a phase separation which changes at least one of optical property and electrical property of the recording material.

2. The recording material for the phase change solid memory according to claim 1, wherein the uniform-mixed phase is that each of the Sb—Te alloy phase and the at least one of the Te-containing alkali metal iodide phase and the Te-containing silver iodide phase has a dimension of not more than 5 nm in an uniaxial direction.

3. The recording material for the phase change solid memory according to claim 1, wherein the recording material has a crystal structure that includes a first pair of a tellurium atom and either an alkali metal atom or a silver atom, and a second pair of other tellurium atom and an iodide atom,
the recording material shows a transition between first and second states,
the transition between the first and second states is made by at least one of first and second site exchanges,
the first site exchange is made between the position in the uniaxial direction of the site of the tellurium atom belonging to the first pair and the position in the uniaxial direction of the site of either the alkali metal atom or the silver atom belonging to the first pair,
the second site exchange is made between the position in the uniaxial direction of the site of the other tellurium atom belonging to the second pair and the position in the uniaxial direction of the side of the iodide atom belonging to the second pair.

4. The recording material for the phase change solid memory according to claim 1, wherein the recording material has a crystal structure that includes a first pair of a tellurium atom and either an alkali metal atom or a silver atom, and a second pair of other tellurium atom and an iodide atom,
the recording material shows a transition between first and second states,
in the first state, a first distance in an uniaxial direction between the tellurium atom belonging to the first pair and the other tellurium atom belonging to the second pair is smaller than a second distance in the uniaxial direction between either the alkali metal atom or the silver atom belonging to the first pair and the iodide atom belonging to the second pair, and
in the second state, the first distance is greater than the second distance.

5. The recording material for the phase change solid memory according to claim 4, wherein, in the first state, the sites of the tellurium atom belonging to the first pair and the other tellurium atom belonging to the second pair are positioned in the uniaxial direction inside between the sites of either the alkali metal atom or the silver atom belonging to the first pair and the iodide atom belonging to the second pair, and
in the second state, the sites of either the alkali metal atom or the silver atom belonging to the first pair and the iodide atom belonging to the second pair are positioned in the uniaxial direction inside between the sites of the tellurium atom belonging to the first pair and the other tellurium atom belonging to the second pair.

6. The recording material for the phase change solid memory according to claim 5, wherein the transition between the first and second states is made by a first displacement of the tellurium atom belonging to the first pair, a second displacement of the other tellurium atom belonging to the second pair, a third displacement of either the alkali metal atom or the silver atom belonging to the first pair, and a fourth displacement of the iodide atom belonging to the second pair,
the direction of the first and fourth displacements is generally anti-parallel to the direction of the second and third displacements.

7. The recording material for the phase change solid memory according to claim 1, wherein the recording material has a crystal structure that includes a pair of a tellurium atom and either an alkali metal atom or a silver atom,
the recording material shows a transition between first and second states,
the transition between the first and second states is made by a first displacement of the tellurium atom belonging to the pair, and a second displacement of either the alkali metal atom or the silver atom belonging to the pair, and
the direction of the first displacement is generally anti-parallel to the direction of the second displacement.

8. The recording material for the phase change solid memory according to claim 1, wherein the recording material has a crystal structure that includes a pair of a tellurium atom and an iodide atom,
the recording material shows a transition between first and second states,
the transition between the first and second states is made by a first displacement of the tellurium atom belonging to the pair, and a second displacement of the iodide atom belonging to the pair, and
the direction of the first displacement is generally anti-parallel to the direction of the second displacement.

9. The recording material for the phase change solid memory according to claim 1, wherein the recording material has a crystal structure that includes a first pair of a tellurium atom and either an alkali metal atom or a silver atom, and a second pair of other tellurium atom and an iodide atom,
the recording material shows a transition between first and second states,
the transition between the first and second states is made by a first displacement of the tellurium atom belonging to the first pair, a second displacement of the other tellurium atom belonging to the second pair, a third displacement of either the alkali metal atom or the silver atom belonging to the first pair, and a fourth displacement of the iodide atom belonging to the second pair,
the direction of the first and fourth displacements is generally anti-parallel to the direction of the second and third displacements.

10. A recording material for a phase change solid memory, the recording material comprising: a uniform-mixed phase that includes:
at least one of a Te-containing alkali metal iodide phase and a Te-containing silver iodide phase; and
an Sb—Te alloy phase,
wherein the recording material has a crystal structure that includes a first pair of a tellurium atom and either an alkali metal atom or a silver atom, and a second pair of other tellurium atom and an iodide atom,
the recording material shows a transition between first and second states,
the transition between the first and second states is made by at least one of first and second displacement set,
the first displacement set includes a first displacement of the tellurium atom belonging to the first pair and a second displacement of either the alkali metal atom or the silver atom belonging to the first pair, the directions of the first and second displacements are generally anti-parallel to each other,
the second displacement set includes a third displacement of the other tellurium atom belonging to the second pair and a fourth displacement of the iodide atom belonging to the second pair, the directions of the third and fourth displacements are generally anti-parallel to each other.

11. The recording material for the phase change solid memory according to claim 10, wherein the uniform-mixed phase is that each of the Sb—Te alloy phase and the at least one of the Te-containing alkali metal iodide phase and the Te-containing silver iodide phase has a dimension of not more than 5 nm in an uniaxial direction.

12. A phase change solid memory comprising a recording material, the recording material comprising: a uniform-mixed phase that includes:
at least one of a Te-containing alkali metal iodide phase and a Te-containing silver iodide phase; and
an Sb—Te alloy phase,
wherein the recording material shows at least one of a phase change and a phase separation which changes at least one of optical property and electrical property of the recording material.

13. The phase change solid memory according to claim 12, wherein the uniform-mixed phase is that each of the Sb—Te alloy phase and the at least one of the Te-containing alkali metal iodide phase and the Te-containing silver iodide phase has a dimension of not more than 5 nm in an uniaxial direction.

14. The phase change solid memory according to claim 12, wherein the recording material has a crystal structure that includes a first pair of a tellurium atom and either an alkali metal atom or a silver atom, and a second pair of other tellurium atom and an iodide atom,
the recording material shows a transition between first and second states,
the transition between the first and second states is made by at least one of first and second site exchanges,
the first site exchange is made between the position in the uniaxial direction of the site of the tellurium atom belonging to the first pair and the position in the uniaxial direction of the site of either the alkali metal atom or the silver atom belonging to the first pair,
the second site exchange is made between the position in the uniaxial direction of the site of the other tellurium atom belonging to the second pair and the position in the uniaxial direction of the side of the iodide atom belonging to the second pair.

15. The phase change solid memory according to claim 12, wherein the recording material has a crystal structure that includes a first pair of a tellurium atom and either an alkali metal atom or a silver atom, and a second pair of other tellurium atom and an iodide atom,
the recording material shows a transition between first and second states,
in the first state, a first distance in an uniaxial direction between the tellurium atom belonging to the first pair and the other tellurium atom belonging to the second pair is smaller than a second distance in the uniaxial direction between either the alkali metal atom or the silver atom belonging to the first pair and the iodide atom belonging to the second pair, and
in the second state, the first distance is greater than the second distance.

16. The phase change solid memory according to claim 15, wherein, in the first state, the sites of the tellurium atom belonging to the first pair and the other tellurium atom belonging to the second pair are positioned in the uniaxial direction inside between the sites of either the alkali metal atom or the silver atom belonging to the first pair and the iodide atom belonging to the second pair, and
in the second state, the sites of either the alkali metal atom or the silver atom belonging to the first pair and the iodide atom belonging to the second pair are positioned in the uniaxial direction inside between the sites of the tellurium atom belonging to the first pair and the other tellurium atom belonging to the second pair.

17. The phase change solid memory according to claim 16, wherein the transition between the first and second states is made by a first displacement of the tellurium atom belonging to the first pair, a second displacement of the other tellurium atom belonging to the second pair, a third displacement of either the alkali metal atom or the silver atom belonging to the first pair, and a fourth displacement of the iodide atom belonging to the second pair,
the direction of the first and fourth displacements is generally anti-parallel to the direction of the second and third displacements.

18. The phase change solid memory according to claim 12, wherein the recording material has a crystal structure that includes a pair of a tellurium atom and either an alkali metal atom or a silver atom,
the recording material shows a transition between first and second states,
the transition between the first and second states is made by a first displacement of the tellurium atom belonging to the pair, and a second displacement of either the alkali metal atom or the silver atom belonging to the pair, and
the direction of the first displacement is generally anti-parallel to the direction of the second displacement.

19. The phase change solid memory according to claim 12, wherein the recording material has a crystal structure that includes a pair of a tellurium atom and an iodide atom,
the recording material shows a transition between first and second states,
the transition between the first and second states is made by a first displacement of the tellurium atom belonging to the pair, and a second displacement of the iodide atom belonging to the pair, and
the direction of the first displacement is generally anti-parallel to the direction of the second displacement.

20. The phase change solid memory according to claim 12, wherein the recording material has a crystal structure that includes a first pair of a tellurium atom and either an alkali metal atom or a silver atom, and a second pair of other tellurium atom and an iodide atom,
the recording material shows a transition between first and second states,
the transition between the first and second states is made by a first displacement of the tellurium atom belonging to the first pair, a second displacement of the other tellurium atom belonging to the second pair, a third displacement of either the alkali metal atom or the silver atom belonging to the first pair, and a fourth displacement of the iodide atom belonging to the second pair,
the direction of the first and fourth displacements is generally anti-parallel to the direction of the second and third displacements.
